(19) United States
(12) Patent Application Publication
(10) Pub. No.: US 2026/0334170 A1
(43) Pub. Date: Oct. 22, 2026

(54) SEMICONDUCTOR DEVICE

(71) Applicant: Samsung Electronics Co., Ltd., Suwon-si (KR)

(72) Inventors: Gyu Baek LEE, Suwon-si (KR); Wook Hyun KWON, Suwon-si (KR); Ki Sung LEE, Suwon-si (KR)

(21) Appl. No.: 19/459,585

(22) Filed: Jan. 26, 2026

(30) Foreign Application Priority Data
Apr. 17, 2025 (KR) 10-2025-0050136

(51) Int. Cl. H10P 74/00

(52) U.S. Cl. CPC H10P 74/273

(57) ABSTRACT

A semiconductor device includes a substrate including a plurality of cell areas and a scribe lane area defining the plurality of cell areas; a first test element group on the scribe lane area; a second test element group on the scribe lane area; and a third test element group on the scribe lane area. The first test element group includes a plurality of first wells spaced apart along a first direction and containing impurities of a first conductivity type. The second test element group includes a plurality of second wells spaced apart from each other along the first direction and containing impurities of the first conductivity type. The third test element group includes a third well containing impurities of the first conductivity type.

### CROSS-REFERENCE TO RELATED APPLICATION

This application claims, under 35 U.S.C. 119, the benefit of and priority to Korean Patent Application No. 10-2025-0050136 filed on Apr. 17, 2025, in the Korean Intellectual Property Office, the contents of which in its entirety are herein incorporated by reference.

### BACKGROUND

A phenomenon such as diffusion of impurities in a well may occur due to heat of a subsequent process. As a result, a change in a threshold voltage of a transistor may occur, which may cause a defect in the semiconductor device.

### SUMMARY

The present disclosure relates to a semiconductor device.

Aspects of the present disclosure provide a semiconductor device with improved product reliability.

Aspects of the present disclosure provide a method for analyzing a concentration of impurities or a concentration of carriers in a semiconductor device.

The technical purposes of the present disclosure are not limited to the technical purposes mentioned above, and other technical purposes not mentioned may be clearly understood by those skilled in the art from the following description.

According to an aspect of the present disclosure, there is provided a semiconductor device including a substrate including a plurality of cell areas and a scribe lane area defining the plurality of cell areas; a first test element group on the scribe lane area; a second test element group on the scribe lane area; and a third test element group on the scribe lane area, wherein the first test element group includes a plurality of first wells spaced apart along a first direction and containing impurities of a first conductivity type, wherein the second test element group includes a plurality of second wells spaced apart from each other along the first direction and containing impurities of the first conductivity type, wherein the third test element group includes a third well containing impurities of the first conductivity type.

According to the aforementioned and other implementations of the present disclosure, there is provided a semiconductor device including a substrate including a plurality of cell areas and a scribe lane area defining the plurality of cell areas; a first test element group on the scribe lane area; and a second test element group on the scribe lane area, wherein the first test element group includes a first well and a first reference well containing impurities of a first conductivity type and spaced apart from each other in a first direction, wherein the first well has a first length in the first direction, wherein the first reference well has a second length greater than the first length in the first direction, wherein the second test element group includes a second well containing impurities of the first conductivity type.

According to the aforementioned and other implementations of the present disclosure, there is provided a semiconductor device including a substrate including a plurality of cell areas and a scribe lane area defining the plurality of cell areas; a first test element group on the scribe lane area; a second test element group on the scribe lane area; and a third test element group on the scribe lane area, wherein the first test element group includes a plurality of first wells spaced apart along a first direction and containing impurities of a first conductivity type, wherein the second test element group includes a plurality of well pairs spaced apart from each other along the first direction, wherein each of the plurality of well pairs includes a second well containing impurities of the first conductivity type and a third well containing impurities of a second conductivity type different from the first conductivity type, wherein the third test element group includes a fourth well containing impurities of the first conductivity type.

Specific details of other implementations are included in the detailed description and drawings.

### BRIEF DESCRIPTION OF DRAWINGS

The above and other aspects and features of the present disclosure will become more apparent by illustrating in detail implementations thereof with reference to the attached drawings, in which:

FIG. 1 is a view for illustrating a semiconductor device according to some implementations;

FIG. 2 is a flowchart illustrating a method for analyzing a concentration of impurities in a semiconductor device according to some implementations;

FIGS. 3 to 13 are diagrams for illustrating operation S110 of FIG. 2;

FIG. 14 is a diagram for illustrating operations S120 and S130 of FIG. 2;

FIG. 15 is a diagram for illustrating operation S140 of FIG. 2;

FIGS. 16 and 17 are diagrams for illustrating a method for analyzing a concentration of impurities in the semiconductor device of FIG. 2;

FIGS. 18 to 25 are diagrams for illustrating a method for analyzing a concentration of impurities in the semiconductor device of FIG. 2;

FIGS. 26 and 27 are diagrams for illustrating a method for analyzing a concentration of impurities in the semiconductor device of FIG. 2;

FIG. 28 is a flowchart illustrating a method for analyzing a concentration of carriers of a semiconductor device according to some implementations;

FIGS. 29 to 38 are diagrams for illustrating a method for analyzing a concentration of carriers in the semiconductor device of FIG. 28;

FIGS. 39 to 41A, 41B and 41C are diagrams for illustrating a method for analyzing a concentration of carriers in the semiconductor device of FIG. 28;

FIGS. 42 to 44 are diagrams for illustrating a method for analyzing a concentration of carriers in the semiconductor device of FIG. 28; and

FIG. 45 is a diagram for illustrating a system for analyzing a concentration of impurities and a concentration of carriers according to some implementations.

### DETAILED DESCRIPTION

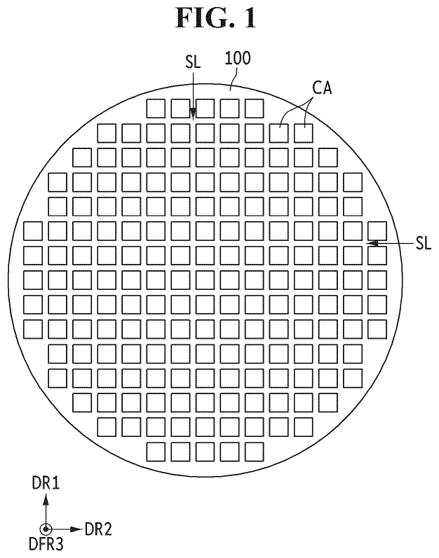

FIG. 1 is a view for illustrating a semiconductor device according to some implementations.

Referring to FIG. 1, the semiconductor device according to some implementations may include a substrate 100.

The substrate 100 may be a wafer including silicon, germanium, silicon-germanium, or a Group IIIV-compound such as GaP, GaAs, GaSb, or the like. According to some implementations, the substrate 100 may be a Silicon On Insulator (SOI) wafer or a Germanium On Insulator (GOI) wafer. Hereinafter, a first direction DR1 and a second direction DR2 may be parallel to an upper surface of the substrate 100. The second direction DR2 may intersect the first direction DR1.

The substrate 100 may include a plurality of cell areas CA and a scribe lane area SL. The cell areas CA may be spaced apart from each other in each of the first direction DR1 and the second direction DR2. The scribe lane area SL may surround the cell area CA. The cell area CA may be defined by the scribe lane area SL.

A dicing process may be performed along the scribe lane area SL to form a plurality of semiconductor chips, each including the cell area CA. The scribe lane area SL may be partially or entirely removed in the dicing process. The semiconductor chip may be, for example, a central processing unit (CPU) chip, a graphic processing unit (GPU) chip, or an application processor (AP) chip. The semiconductor chip may be, for example, a dynamic random access memory (DRAM) chip, a static random access memory (SRAM) chip, a flash memory chip, an electrically erasable and programmable read-only memory (EEPROM) chip, a phase-change random access memory (PRAM) chip, a magnetic random access memory (MRAM) chip, or a resistive random access memory (RRAM) chip.

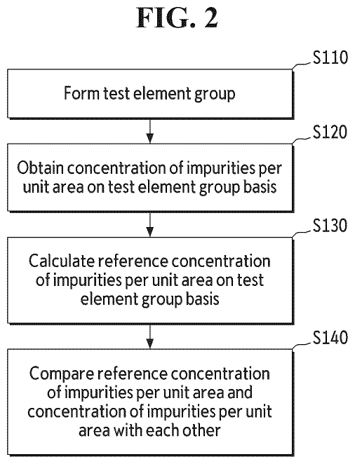

FIG. 2 is a flowchart illustrating a method for analyzing a concentration of impurities in a semiconductor device according to some implementations.

Referring to FIG. 2, a test element group may be formed in S110. A concentration of impurities per unit area may be obtained on a test element group basis in S120. A reference concentration of impurities per unit area may be calculated on a test element group basis in S130. The reference concentration of impurities per unit area and the concentration of impurities per unit area may be compared with each other in S140.

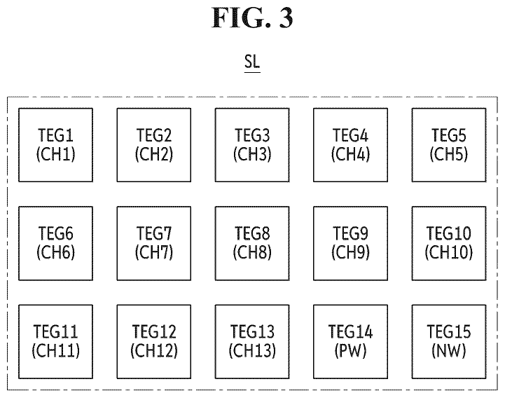

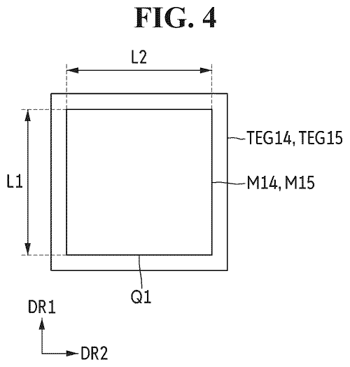

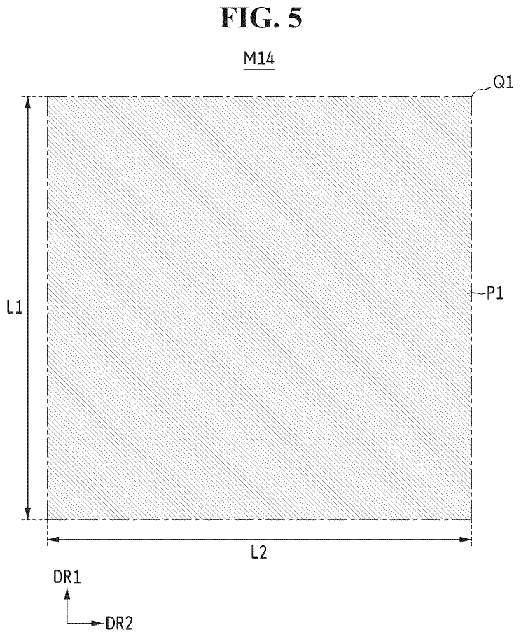

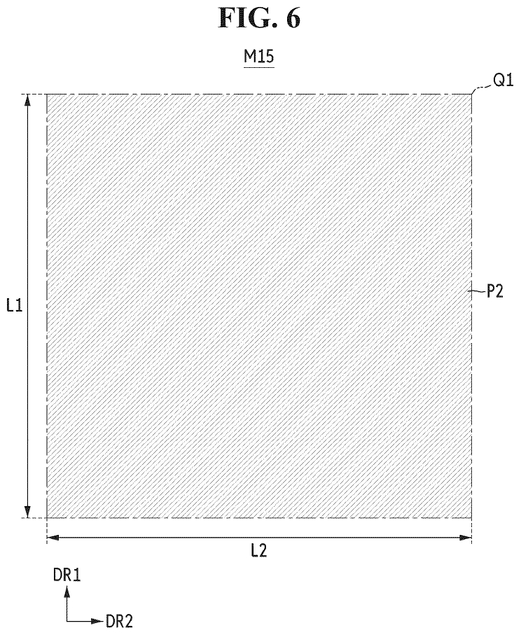

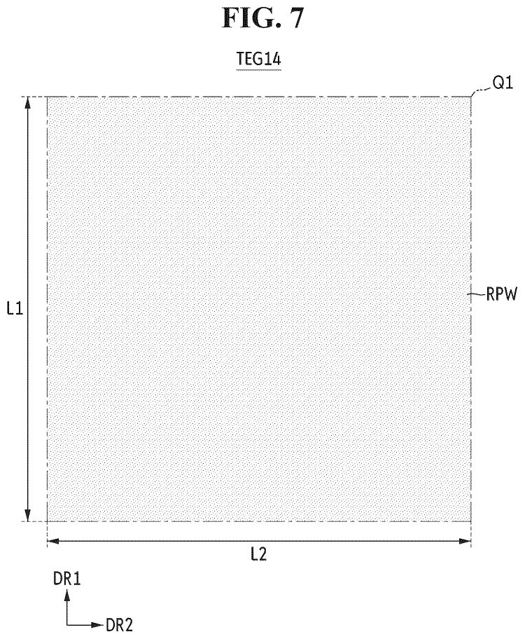

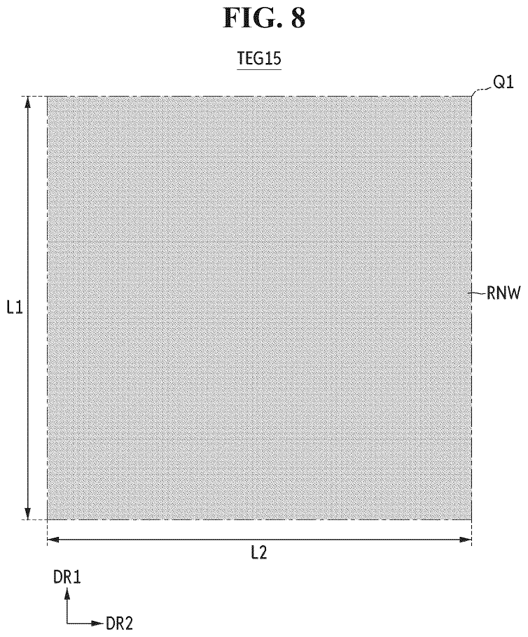

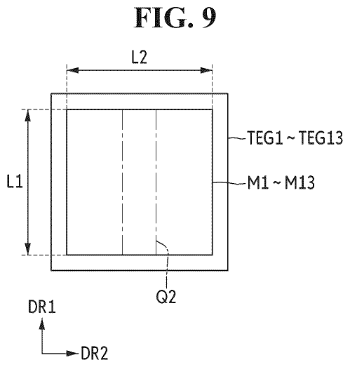

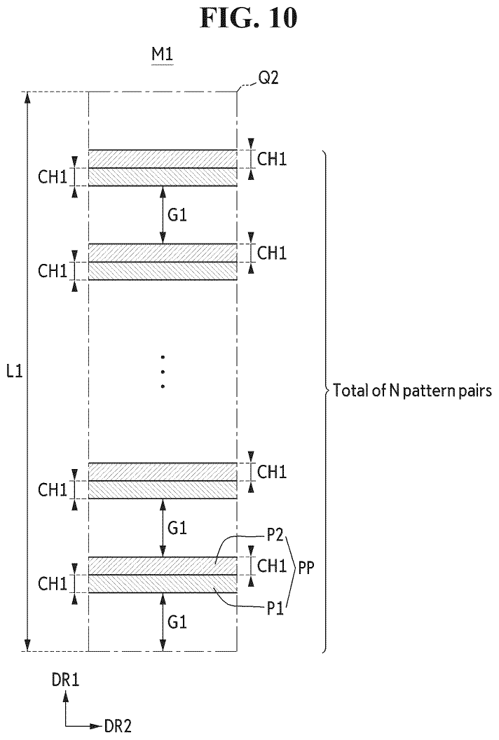

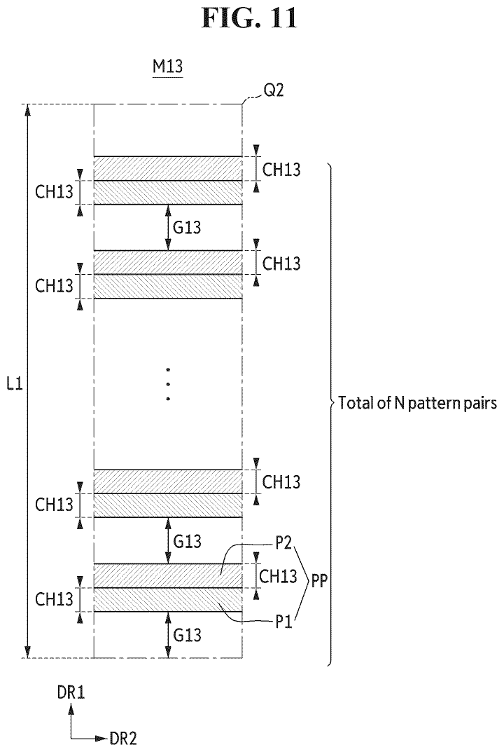

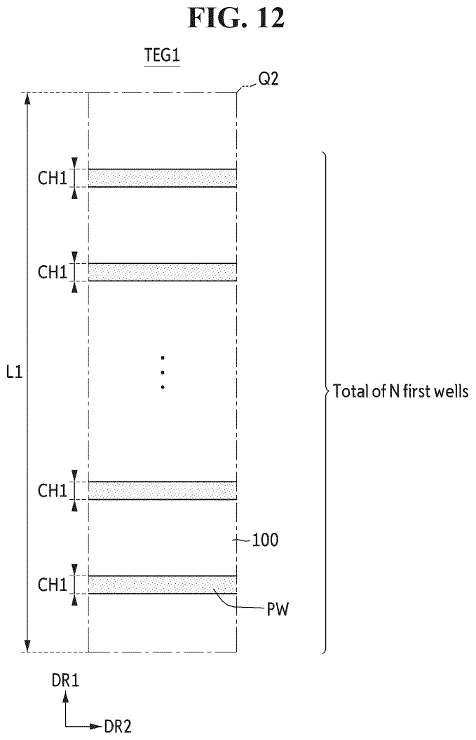

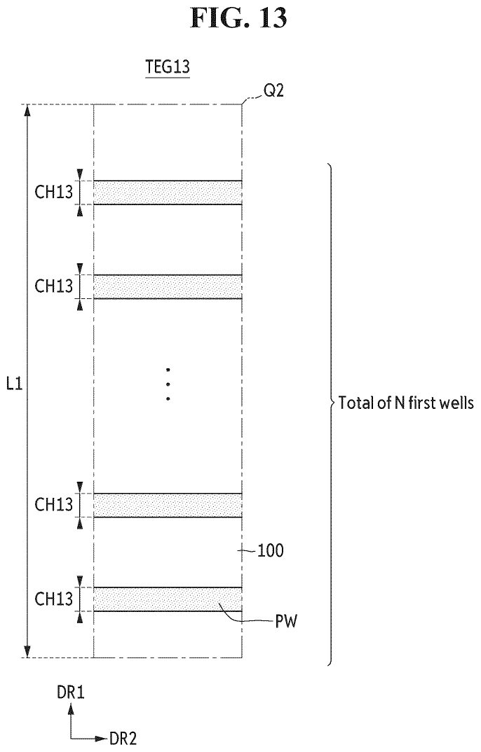

FIGS. 3 to 13 are diagrams for illustrating operation S110 of FIG. 2. FIG. 4 is a diagram illustrating a 14th test element group TEG14, a 15th test element group TEG15, a 14th mask layout M14, and a 15th mask layout M15 of FIG. 3. FIG. 5 is an enlarged view of an area Q1 of the 14th mask layout M14 of FIG. 4. FIG. 6 is an enlarged view of an area Q1 of the 15th mask layout M15 of FIG. 4. FIG. 7 is an enlarged view of an area Q1 of the 14th test element group TEG14 of FIG. 4. FIG. 8 is an enlarged view of an area Q1 of the 15th test element group TEG15 of FIG. 4. FIG. 9 is a diagram illustrating first to 13th test element groups TEG1 to TEG13 of FIG. 3 and first to 13th mask layouts M1 to M13. FIG. 10 is an enlarged view of an area Q2 of the first mask layout M1 of FIG. 9. FIG. 11 is an enlarged view of an area Q2 of the thirteenth mask layout M13 of FIG. 9. FIG. 12 is an enlarged view of an area Q2 of the first test element group TEG1 of FIG. 9. FIG. 13 is an enlarged view of an area Q2 of the thirteenth test element group TEG13 of FIG. 9.

Referring to FIG. 3, a plurality of test element groups TEG1 to TEG15 may be formed on the scribe lane area SL in S110 of FIG. 2. For example, the first to 15th test element groups TEG1 to TEG15 may be formed on the scribe lane area SL. The first to 15th test element groups TEG1 to TEG15 may have the same size. For example, lengths of the first to 15th test element groups TEG1 to TEG15 in the first direction DR1 may be equal to each other, and lengths of the first to 15th test element groups TEG1 to TEG15 in the second direction DR2 may be equal to each other. The number of the test element groups TEG1 to TEG15 formed on the scribe lane area SL is not limited thereto.

Referring to FIGS. 3 to 13, each of the first to 15th test element groups TEG1 to TEG15 may include at least one well of a first well PW and a second well NW formed using each of the first to 15th mask layouts M1 to M15. Each of the first to 15th mask layouts M1 to M15 may include at least one pattern of a first pattern P1 and a second pattern P2. The first pattern P1 may correspond to an area in which the first well PW is formed in the substrate 100, and the second pattern P2 may correspond to an area in which the second well NW is formed in the substrate 100. A photoresist pattern may be formed using the first to 15th mask layouts M1 to M15, and an ion implantation process may be performed on the substrate 100 using the photoresist pattern to form the first well PW or the second well NW in the first to 15th test element groups TEG1 to TEG15. The first well PW may include a first conductivity type impurity (e.g., boron), and the second well NW may include a second conductivity type impurity (e.g., arsenic, phosphorus).

Each of the first to 15th mask layouts M1 to M15 may have a first cell length L1 in the first direction DR1 and a second cell length L2 in the second direction DR2. Each of the first pattern P1 and the second pattern P2 may have a second cell length L2 in the second direction DR2. Each of the first cell length L1 and the second cell length L2 may be determined in consideration of a size of the Magnetic Secondary Ion Mass Spectrometry (MSIMS) analysis area.

A length in the first direction DR1 of the first well PW included in each of the first to 15th test element groups TEG1 to TEG15 may be proportional to a length in the first direction DR1 of the first pattern P1 of each of the first to 15th mask layouts M1 to M15. A length in the first direction DR1 of the second well NW included in each of the first to 15th test element groups TEG1 to TEG15 may be proportional to a length of the second pattern P2 in the first direction DR1 of each of the first to 15th mask layouts M1 to M15. Hereinafter, for convenience of description, an example in which the lengths in the first direction DR1 and the second direction DR2 of the first well PW of each of the first to 14th test element groups TEG1 to TEG14 are equal to the lengths in the first direction DR1 and the second direction DR2 of the first pattern P1 of each of the first to 14th mask layouts M1 to M14, respectively will be described. Further, an example in which the lengths in the first direction DR1 and the second direction DR2 of the second well NW of each of the first to 13th test element groups TEG1 to TEG13 and the 15th test element group TEG15 are respectively equal to the lengths in the first direction DR1 and the second direction DR2 of the second pattern P2 of each of the first to 13th mask layouts M1 to M13 and the 15th mask layout M15.

Referring to FIGS. 4 and 5, the 14th mask layout M14 may include one first pattern P1. The first pattern P1 may have a first cell length L1 in the first direction DR1.

Referring to FIGS. 4 and 6, the 15th mask layout M15 may include one second pattern P2. The second pattern P2 may have a first cell length L1 in the first direction DR1.

Referring to FIGS. 4 and 7, the 14th test element group TEG14 may include one first well RPW. The first well RPW may have a first cell length L1 in the first direction DR1. The first well RPW of the 14th test element group TEG14 may be referred to as a first reference well.

Referring to FIGS. 4 and 8, the 15th test element group TEG15 may include one second well RNW. The second well RNW may have a first cell length L1 in the first direction DR1. The second well RNW of the 15th test element group TEG15 may be referred to as a second reference well.

Referring to FIGS. 9 to 11, in some implementations, each of the first to 13th mask layouts M1 to M13 may include the same number, that is, N (N is a natural number of 2 or greater) of pattern pairs PP spaced apart from each other in the first direction DR1. The pattern pair PP may include the first pattern P1 and the second pattern P2 adjacent to each other. A length in the first direction DR1 of the first pattern P1 included in each of the first to 13th mask layouts M1 to M13 may be equal to a length in the first direction DR1 of the second pattern P2 included in each of the first to 13th mask layouts M1 to M13. Respective lengths in the first direction DR1 of the first patterns P1 respectively included in the first to thirteenth mask layouts M1 to M13 may be different from each other. Respective lengths in the first direction DR1 of the second patterns P2 respectively included in the first to thirteenth mask layouts M1 to M13 may be different from each other.

Referring to FIGS. 9 and 10, each of the first pattern P1 and the second pattern P2 of the first mask layout M1 may have a first length CH1 in the first direction DR1. The N pattern pairs PP of the first mask layout M1 may be spaced apart from each other by a first spacing G1 along the first direction DR1.

Referring to FIGS. 9 and 11, each of the first pattern P1 and the second pattern P2 of the 13th mask layout M13 may have a 13th length CH13 in the first direction b. The N pattern pairs PP of the thirteenth mask layout M13 may be spaced apart from each other by a thirteenth spacing G13 in the first direction DR1.

Similarly, the respective first patterns P1 of the second to 12th mask layouts M2 to M12 may have second to 12th lengths CH2 to CH12 in the first direction b, respectively. The respective second patterns P2 of the second to 12th mask layouts M2 to M12 may have the second to 12th lengths CH2 to CH12 in the first direction DR1, respectively. The first to thirteenth lengths CH1 to CH13 may be different from each other. An i-th length CHi (i is a natural number of 2 to 12) may be larger than each of the first to (i−1)-th lengths CH1 to CH(i−1) and smaller than each of the (i+1)-th to 13th lengths CH(i+1) to CH13.

Referring to FIGS. 9, 12, and 13, in some implementations, an ion implantation process using the first to 15th mask layouts M1 to M15 may be performed on the first to 13th test element groups TEG1 to TEG13 to form the first well PW. Each of the first to thirteenth test element groups TEG1 to TEG13 may include N first wells PW spaced apart from each other in the first direction DR1. The first wells PW respectively included in the first to thirteenth test element groups TEG1 to TEG13 may have the first to thirteenth lengths CH1 to CH13 in the first direction DR1, respectively.

Referring to FIGS. 9 and 12, the first test element group TEG1 may include N first wells PW spaced apart from each other in the first direction DR1, each first well having the first length CH1 in the first direction DR1.

Referring to FIGS. 9 and 13, the 13th test element group TEG13 may include N first wells PW spaced apart from each other in the first direction DR1, each first well having the 13th length CH13 in the first direction DR1.

Similarly, each of the second to 12th test element groups TEG 2 to TEG12 may include N first wells PW spaced apart from each other in the first direction DR1. The first wells PW of the second to 12th test element groups TEG2 to TEG12 may have the second to 12th lengths CH2 to CH12 in the first direction DR1, respectively.

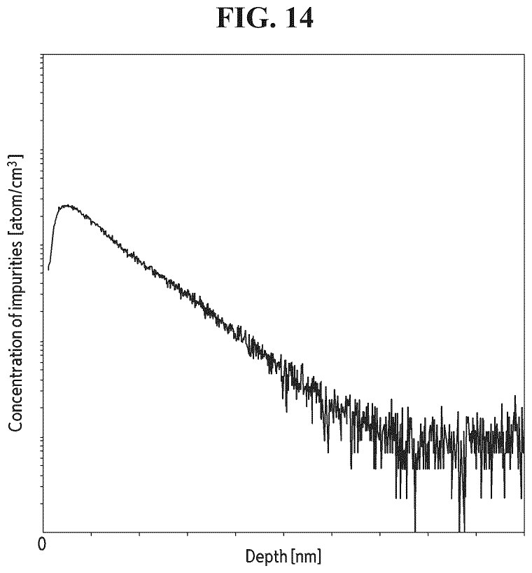

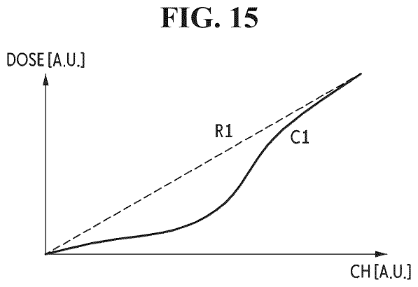

FIG. 14 is a diagram for illustrating operations S120 and S130 of FIG. 2. FIG. 15 is a diagram for illustrating operation S140 of FIG. 2.

The concentration of impurities per unit area in each of the first to 14th test element groups TEG1 to TEG14 may be obtained via the MSIMS in S120 of FIG. 2.

FIG. 14 is a concentration of impurities per unit volume based on a depth of the first test element group TEG1 obtained via the MSIMS. In this regard, the depth refers to a depth from the upper surface of the substrate 100. The concentration of impurities per unit volume based on the depth of the first test element group TEG1 may be integrated with respect to the depth to calculate the concentration of impurities per unit area of the first test element group TEG1. Similarly, the concentration of impurities per unit volume based on the depth of each of the second to 14th test element groups TEG2 to TEG14 may be obtained via the MSIMS. The concentration of impurities per unit volume based on the depth of each of the second to 14th test element groups TEG2 to TEG14 may be integrated with respect to the depth to calculate the concentration of impurities per unit area of each of the second to 14th test element groups TEG2 to TEG14.

In one example, the reference concentration of impurities per unit area of each of the first to 13th test element groups TEG1 to TEG13 may be calculated using the concentration of impurities per unit area of the 14th test element group TEG14 in S130 of FIG. 2.

Specifically, the concentration of impurities in each of the first to thirteenth test element groups TEG1 to TEG13 may be proportional to a size of an area in which the ion implantation process is performed. Since the first to thirteenth test element groups TEG1 to TEG13 have the respective second cell lengths L2 in the second direction DR2 and include the same number of first wells PW, the concentration of impurities in each of the first to thirteenth test element groups TEG1 to TEG13 may be proportional to each of the respective first to thirteenth lengths CH1 to CH13 in the first direction DR1 of the first to thirteenth test element groups TEG1 to TEG13. Accordingly, the reference concentration R1 of impurities per unit area of each of the first to 13th test element groups TEG1 to TEG13 may be expressed based on a following Equation 1.

R1=RP*N*CH/L2 [Equation 1]

In the Equation 1, RP denotes a concentration of impurities per unit area of the first reference well RPW of the 14th test element group TEG14, CH denotes a length in the first direction DR1 of the first well PW of each of the first to 13th test element groups TEG1 to TEG13, and N denotes the number of the first wells PW included in each of the first to 13th test element groups TEG1 to TEG13.

Referring to FIG. 15, the reference concentration R1 of impurities per unit area based on the length CH in the first direction DR1 of the first well PW may be compared with a concentration C1 of impurities per unit area based on the length CH in the first direction DR1 of the first well PW in S140 of FIG. 2. Thus, it may be determined whether the doping of the impurity in the substrate 100 has actually increased or decreased based on the comparing result with the reference concentration of impurities per unit area based on the length CH of the first well PW in the first direction DR1 (i.e., the reference concentration of impurities per unit area in theory).

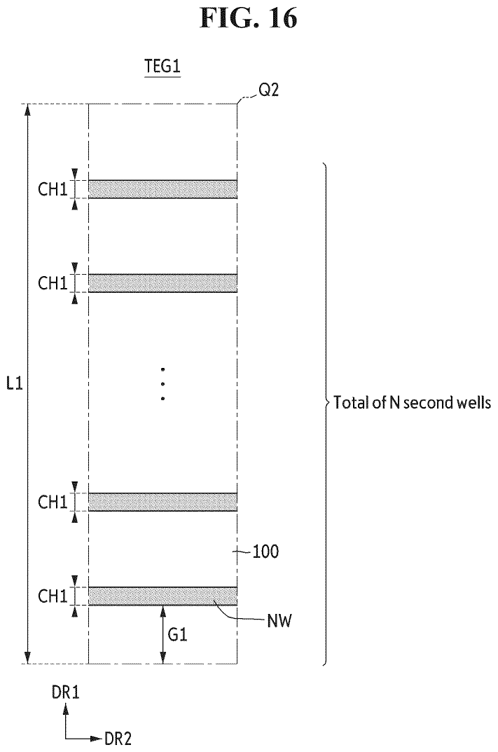

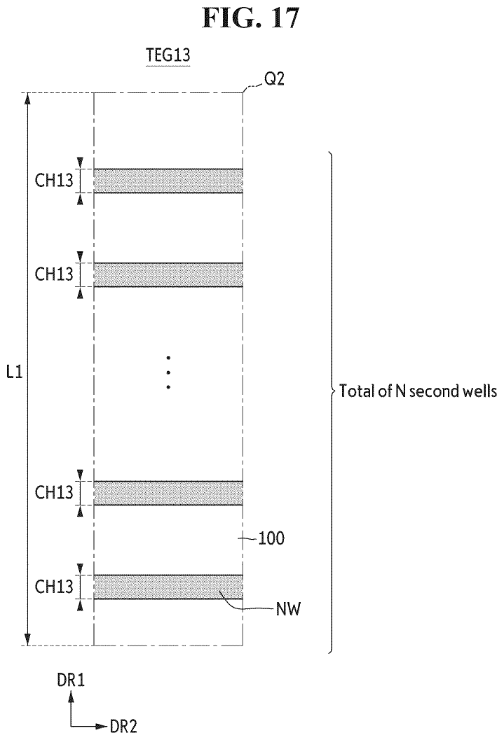

FIGS. 16 and 17 are diagrams for illustrating a method for analyzing a concentration of impurities in the semiconductor device of FIG. 2. For convenience of description, differences from those described with reference to FIGS. 1 to 15 will be mainly described. FIG. 16 is an enlarged view of an area Q2 of the first test element group TEG1 of FIG. 9. FIG. 17 is an enlarged view of an area Q2 of the 13th test element group TEG13 of FIG. 9.

Referring to FIGS. 9, 16, and 17, in some implementations, the first to 13th test element groups TEG1 to TEG13, each including the second well NW, may be formed on the scribe lane area SL in S110 of FIG. 2. An ion implantation process using the first to 15th mask layouts M1 to M15 may be performed on the first to 13th test element groups TEG1 to TEG13 to form the second well NW. Each of the first to thirteenth test element groups TEG1 to TEG13 may include N second wells NW spaced apart from each other in the first direction DR1. The second well NW respectively included in the first to 13th test element groups TEG1 to TEG13 may have first to 13th lengths CH1 to CH13 in the first direction DR1, respectively.

Referring to FIG. 16, the first test element group TEG1 may include N second wells NW spaced apart from each other in the first direction DR1, each having the first length CH1 in the first direction DR1.

Referring to FIG. 17, the 13th test element group TEG13 may include N second wells NW spaced apart from each other in the first direction DR1, each having the 13th length CH13 in the first direction DR1.

Similarly, each of the second to 12th test element groups TEG 2 to TEG12 may include N second wells NW spaced apart from each other in the first direction DR1. The second wells NW of the second to 12th test element groups TEG2 to TEG12 may have second to 12th lengths CH2 to CH12 in the first direction DR1, respectively.

As described above, the concentration of impurities per unit volume based on the depth of each of the first to 13th test element groups TEG1 to TEG13 and the 15th test element group TEG15 may be obtained via the MSIMS in S120 of FIG. 2. In addition, the concentration of impurities per unit area based on the depth of each of the first to 13th test element groups TEG1 to TEG13 and the 15th test element group TEG15 may be calculated in S130 of FIG. 2.

The reference concentration of impurities per unit area of each of the first to 13th test element groups TEG1 to TEG13 may be calculated using the concentration of impurities per unit area of the 15th test element group TEG15. The reference concentration R1′ of impurities per unit area of each of the first to thirteenth test element groups TEG1 to TEG13 may be expressed based on a following Equation 2.

R1′=RN*N*CH/L2 [Equation 2]

In the Equation 2, RN denotes a concentration of impurities per unit area of the second reference well RNW of the 15th test element group TEG15, CH denotes a length in the first direction DR1 of the second well NW of each of the first to 13th test element groups TEG1 to TEG13, and N denotes the number of the second wells NW included in each of the first to 13th test element groups TEG1 to TEG13.

A reference concentration R2 of impurities per unit area based on the length CH in the first direction DR1 of the second well NW may be compared with the concentration of impurities per unit area based on the length CH in the first direction DR1 of the second well NW in S140 of FIG. 2. Thus, whether the doping of the impurity in the substrate 100 has actually increased or decreased may be determined based on a comparing result with the reference concentration of impurities per unit area based on the length CH in the first direction DR1 of the second well NW.

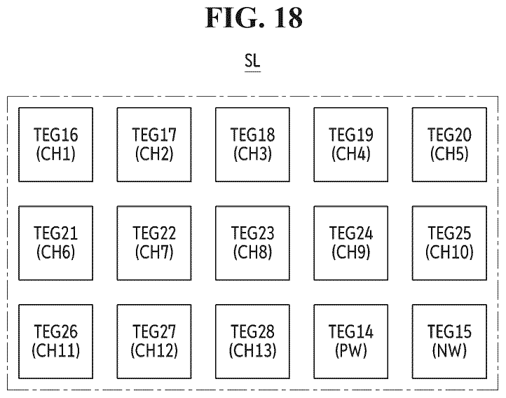

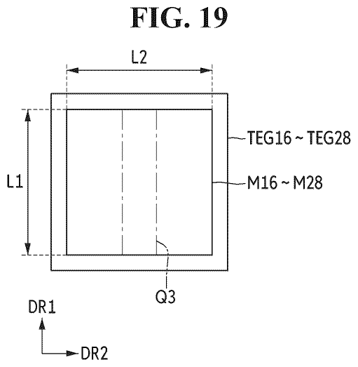

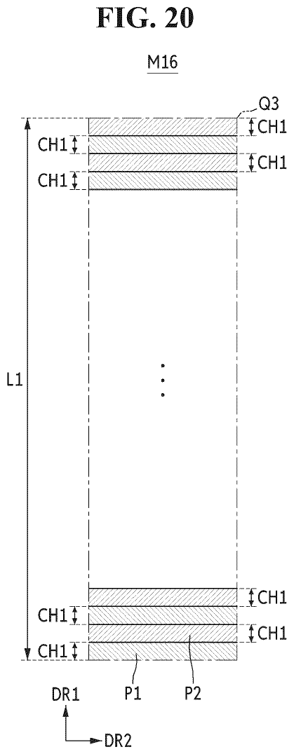

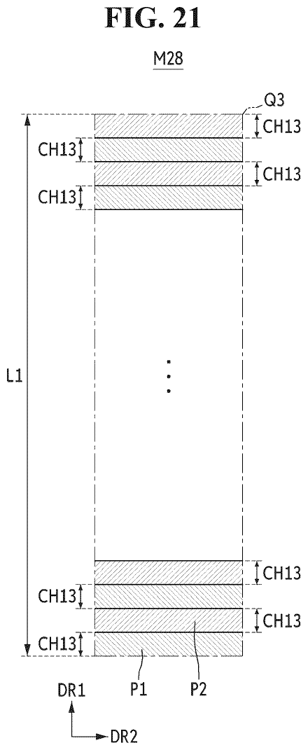

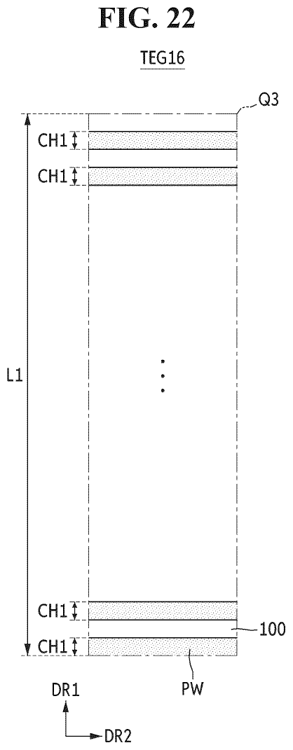

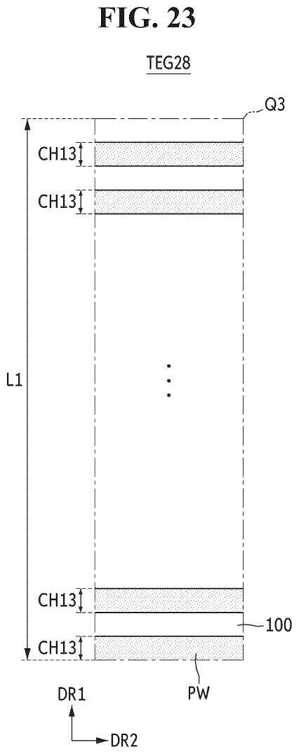

FIGS. 18 to 25 are diagrams for illustrating a method for analyzing a concentration of impurities in the semiconductor device of FIG. 2. For convenience of description, differences from those described with reference to FIGS. 1 to 17 will be mainly described. FIG. 19 is a diagram illustrating 16th to 28th test element groups TEG16 to TEG28 of FIG. 18, and 16th to 28th mask layouts M16 to M28. FIG. 20 is an enlarged view of an area Q3 of the 16th mask layout M16 of FIG. 19. FIG. 21 is an enlarged view of an area Q3 of the 28th mask layout M28 of FIG. 19. FIG. 22 is an enlarged view of an area Q3 of the 16th test element group TEG16 of FIG. 19. FIG. 23 is an enlarged view of an area Q3 of the 28th test element group TEG28 of FIG. 19.

Referring to FIG. 18, a plurality of test element groups TEG14 to TEG 28 may be formed on the scribe lane area SL in S110 of FIG. 2. For example, the 14th to 28th test element groups TEG14 to TEG28 may be formed on the scribe lane area SL. The 14th to 28th test element groups TEG14 to TEG28 may have the same size. The number of the test element groups TEG14 to TEG28 formed on the scribe lane area SL is not limited thereto.

Each of the 14th to 28th test element groups TEG14 to TEG28 may include a well formed using each of the 14th to 28th mask layouts M14 to M28.

In some implementations, each of the 16th to 28th mask layouts M16 to M28 may include first patterns P1 and second patterns P2 which have the same length in the first direction DR1 and are alternately arranged with each other along the first direction DR1. The lengths in the first direction DR1 of the first patterns P1 respectively included in the 16th to 28th mask layouts M16 to M28 may be different from each other. The lengths in the first direction DR1 of the second patterns P2 respectively included in the 16th to 28th mask layouts M16 to M28 may be different from each other.

Referring to FIG. 20, each of the first pattern P1 and the second pattern P2 of the 16th mask layout M16 may have a first length CH1 in the first direction DR1.

Referring to FIG. 21, each of the first pattern P1 and the second pattern P2 of the 28-th mask layout M28 may have a thirteenth length CH13 in the first direction DR1.

Similarly, the first patterns P1 of the 17th to 27th mask layouts M17 to M27 may have the second to 12th lengths CH2 to CH12 in the first direction DR1, respectively. The second patterns P2 of the 17th to 27th mask layouts M17 to M27 may have the second to 12th lengths CH2 to CH12 in the first direction DR1, respectively. The i-th length CHi (i is a natural number of 2 to 12) may be larger than each of the first to (i−1)-th lengths CH1 to CH(i−1) and may be smaller than each of the (i+1)-th to 13th lengths CH(i+1) to CH13.

Referring to FIGS. 19, 22, and 23, in some implementations, an ion implantation process using the 16th to 28th mask layouts M16 to M28 may be performed on the 16th to 28th test element groups TEG16 to TEG28 to form the first well PW. Each of the 16th to 28th test element groups TEG16 to TEG28 may include N first wells PW spaced apart from each other in the first direction DR1. The first wells PW respectively included in the 16th to 28th test element groups TEG16 to TEG28 may have first to 13th lengths CH1 to CH13 in the first direction DR1, respectively.

Referring to FIGS. 19 and 22, the 16th test element group TEG16 may include first wells PW spaced apart from each other in the first direction DR1, each first well having a first length CH1 in the first direction DR1.

Referring to FIGS. 19 and 23, the 28th test element group TEG28 may include first wells PW spaced apart from each other in the first direction DR1, each first well having a 13th length CH13 in the first direction DR1.

Similarly, each of the 17th to 27th test element groups TEG17 to TEG27 may include first wells PW spaced apart from each other in the first direction DR1. Respective first wells PW of the 17th to 27th test element groups TEG17 to TEG27 have second to 12th lengths CH2 to CH12 in the first direction DR1, respectively.

The concentration of impurities per unit area of each of the 16th to 28th test element groups TEG16 to TEG28 may be obtained via the MSIMS in S120 of FIG. 2.

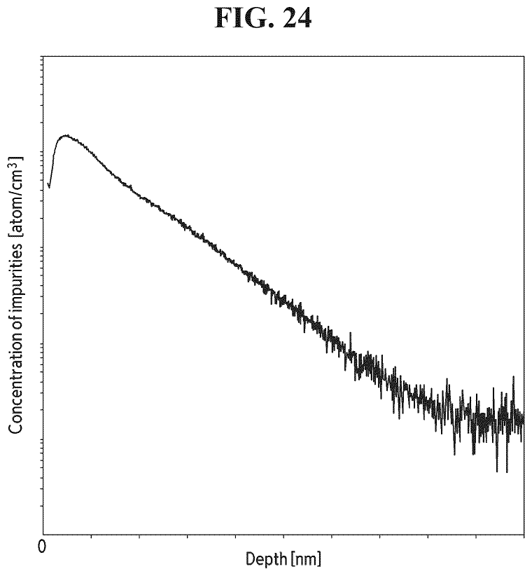

FIG. 24 is a concentration of impurities per unit volume based on the depth of the 16th test element group TEG16 obtained via the MSIMS. The concentration of impurities per unit volume based on the depth of the 16th test element group TEG16 may be integrated with respect to the depth to calculate the concentration of impurities per unit area of the 16th test element group TEG16. Similarly, the concentration of impurities per unit area of each of the 17th to 28th test element groups TEG17 to TEG28 may be calculated using the MSIMS.

In this regard, the reference concentration of impurities per unit area of each of the 16th to 28th test element groups TEG16 to TEG28 may be calculated using the concentration of impurities per unit area of the 14th test element group TEG14 in S130 of FIG. 2.

Specifically, the concentration of impurities in each of the 16th to 28th test element groups TEG16 to TEG28 may be proportional to a size of an area in which the ion implantation process is performed. The 16th to 28th test element groups TEG16 to TEG28 have the first wells PW having the first to 13th lengths CH1 to CH13 in the first direction DR1, respectively such that the first wells PW are spaced apart from each other in the first direction DR1 by the first to 13th lengths CH1 to CH13, respectively. Thus, ½ of the MSIMS analysis area may be an area of the first well PW. Accordingly, the reference concentration R2 of the impurities per unit area of each of the 16th to 28th test element groups TEG16 to TEG28 may be expressed based on a following Equation 3.

R2=RP/2 [Equation 3]

In the Equation 3, RP denotes the concentration of impurities per unit area of the first reference well RPW of the 14th test element group TEG14.

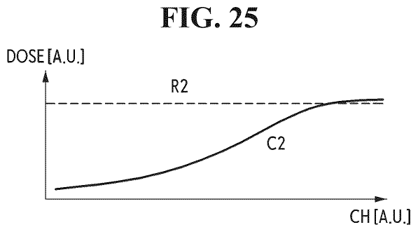

Referring to FIG. 25, the reference concentration R2 of impurities per unit area based on the length of the first well PW in the first direction DR1 may be compared with a concentration C2 of impurities per unit area based on the length of the first well PW in the first direction DR1 in S140 of FIG. 2. Thus, based on the comparing result with the reference concentration of impurities per unit area based on the length CH of the first well PW in the first direction DR1, it may be determined whether the doping of the impurity in the substrate 100 has actually increased or decreased.

In the ion implantation process, as a size of an area of the substrate 100 not covered with the photoresist pattern PR becomes smaller, a small amount of ions are provided to the substrate 100, and thus the concentration of impurities in the substrate 100 may be lowered. In addition, due to electrical repulsion between ions accumulated in the photoresist pattern PR and ions provided to the substrate 100 in the ion implantation process, the ions provided to the substrate 100 may move to be deflected toward the substrate 100, and thus, the concentration of impurities in the substrate 100 may increase. In this case, boron has a smaller mass than arsenic, such that the deflection amount of boron may be greater than that of arsenic. Therefore, the second well NW may have a smaller increase in impurity doping due to the motion deflection of impurities than the first well PW may have. Using the method for analyzing a concentration of impurities of FIG. 2, the increase or the decrease in doping of impurities due to the above phenomenon may be identified.

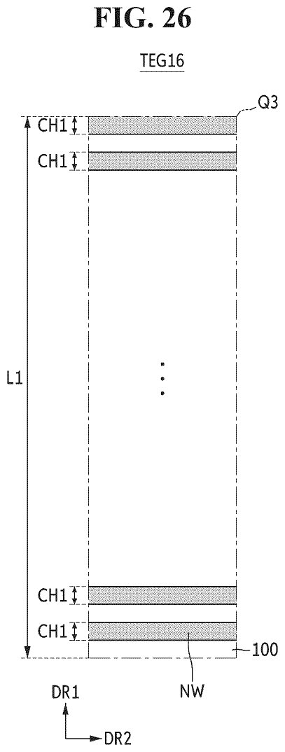

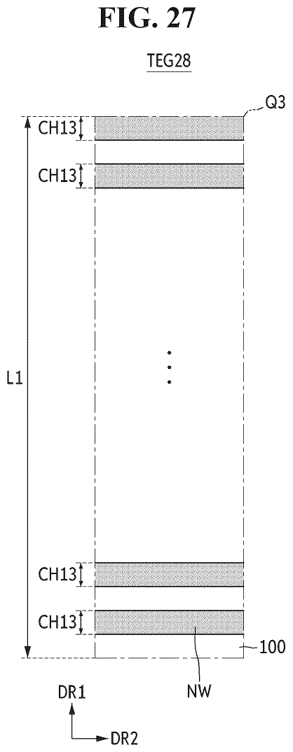

FIGS. 26 and 27 are diagrams for illustrating a method for analyzing a concentration of impurities in the semiconductor device of FIG. 2. For convenience of description, differences from those described with reference to FIGS. 1 to 25 will be mainly described. FIG. 26 is an enlarged view of an area Q3 of the 16th test element group TEG16 of FIG. 19. FIG. 27 is an enlarged view of an area Q3 of the 28th test element group TEG28 of FIG. 19.

Referring to FIGS. 19, 26, and 27, in some implementations, 16th to 28th test element groups TEG16 to TEG28 including the second well NW may be formed on the scribe lane area SL in S110 of FIG. 2. An ion implantation process using the 16th to 28th mask layouts M16 to M28 may be performed on the 16th to 28th test element groups TEG16 to TEG28 to form the second well NW. Each of the 16th to 28th test element groups TEG16 to TEG28 may include N second wells NW spaced apart from each other in the first direction DR1. The second wells NW respectively included in the 16th to 28th test element groups TEG16 to TEG28 may have first to 13th lengths CH1 to CH13 in the first direction DR1 respectively.

Referring to FIGS. 19 and 26, the 16th test element group TEG16 may include second wells NW spaced apart from each other in the first direction DR1, each having a first length CH1 in the first direction DR1.

Referring to FIGS. 19 and 27, the 28th test element group TEG28 may include second wells NW spaced apart from each other in the first direction DR1, each having a 13th length CH13 in the first direction DR1.

Similarly, each of the 17th to 27th test element groups TEG17 to TEG27 may include second wells NW spaced apart from each other in the first direction DR1. In this regard, the second wells NW 17th to 27 of the test element groups TEG17 to TEG27 have second to 12th lengths CH2 to CH12 in the first direction DR1, respectively.

As described above, the concentration of impurities per unit volume based on the depth of each of the 16th to 28th test element groups TEG16 to TEG28 may be obtained via the MSIMS in S120 of FIG. 2. In addition, the concentration of impurities per unit area based on the depth of each of the 16th to 28th test element groups TEG16 to TEG28 may be calculated in S130 of FIG. 2.

The reference concentration R2′ of the impurities per unit area of each of the 16th to 28th test element groups TEG16 to TEG28 may be expressed based on a following Equation 4.

R2′=RN/2 [Equation 4]

In the Equation 4, RN denotes the concentration of impurities per unit area of the second reference well RNW of the 15th test element group TEG15.

The reference concentration R2 of impurities per unit area based on the length of the second well NW in the first direction DR1 may be compared with the concentration C2 of impurities per unit area based on the length of the second well NW in the first direction DR1 in S140 of FIG. 2. Thus, based on the comparing result with the reference concentration of impurities per unit area based on the length CH of the second well NW in the first direction DR1 (i.e., the reference concentration of impurities per unit area in theory), it may be determined whether the doping of the impurity in the substrate 100 has actually increased or decreased.

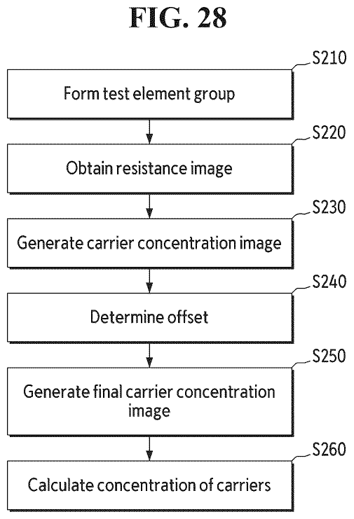

FIG. 28 is a flowchart illustrating a method for analyzing a concentration of carriers of a semiconductor device according to some implementations. For convenience of description, differences from those described with reference to FIGS. 1 to 27 will be mainly described.

Referring to FIG. 28, a test element group may be formed in S210. A resistance image of the test element group may be obtained in S220. A carrier concentration image of the test element group may be generated in S230. An offset for correcting a contact resistance may be determined in S240. A final carrier concentration image of the test element group may be generated in S250. The concentration of carriers of the test element group may be calculated in S260.

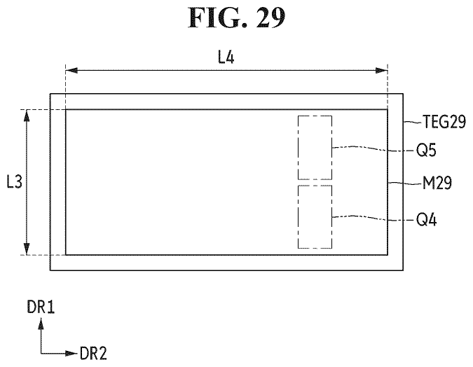

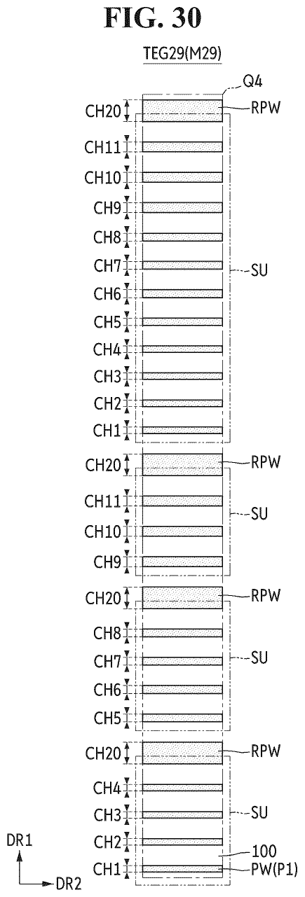

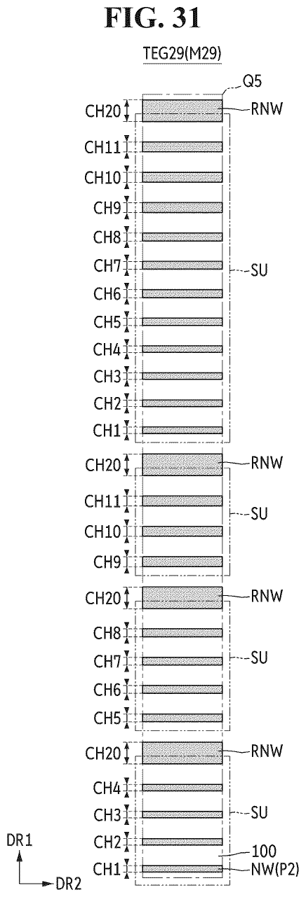

FIGS. 29 to 38 are diagrams for illustrating a method for analyzing a concentration of carriers in the semiconductor device of FIG. 28. FIG. 29 is a diagram illustrating a 29th test element group TEG29 and a 29th mask layout M29. FIG. 30 is an enlarged view of an area Q4 of FIG. 29. FIG. 31 is an enlarged view of an area Q5 of FIG. 29.

Referring to FIGS. 29 to 31, the 29th test element group TEG29 may be formed on the scribe lane area SL of FIG. 1 in S210 of FIG. 28. The 29th test element group TEG29 may include a first well PW and a second well NW formed using the 29th mask layout M29. The 29th mask layout M29 may include a first pattern P1 and a second pattern P2. The 29th mask layout M29 may have a third cell length L3 in the first direction DR1 and a fourth cell length L4 in the second direction DR2. Each of the first pattern P1 and the second pattern P2 may have a fourth cell length L4 in the second direction DR2. The third cell length L3 and the fourth cell length L4 may be determined in consideration of the size of a SSRM scan area SA.

A first area of the 29th mask layout M29 may include first patterns P1 spaced apart from each other along the first direction DR1 and having a 20th length CH20 in the first direction DR1. The first patterns P1 having different lengths in the first direction DR1 may be formed in areas of the 29th mask layout M29 isolated from each other via the first pattern P1 having the 20th length CH20 in the first direction DR1. Accordingly, the 29th test element group TEG29 may include first wells PW spaced apart from each other along the first direction DR1 and having a 20th length CH20 in the first direction DR1. First wells PW having different lengths in the first direction DR1 may be formed in areas of the 29th test element group TEG29 isolated from each other via the first well PW having the 20th length CH20 in the first direction DR1. The first well PW having the 20th length CH20 in the first direction DR1 may be referred to as a third reference well RPW.

A second area of the 29th mask layout M29 may include second patterns P2 spaced apart from each other along the first direction DR1 and having a 20th length CH20 in the first direction DR1. Second patterns P2 having different lengths in the first direction DR1 may be formed in areas of the 29th mask layout M29 isolated from each other via the second pattern P2 having the 20th length CH20 in the first direction DR1. Accordingly, the 29th test element group TEG29 may include second wells NW spaced apart from each other along the first direction DR1 and having a 20th length CH20 in the first direction DR1. Second wells NW having different lengths in the first direction DR1 may be formed in areas of the 29th test element group TEG29 isolated from each other via the second well NW having a 20th length CH20 in the first direction DR1. The second well NW having the 20th length CH20 in the first direction DR1 may be referred to as a fourth reference well RNW.

The resistance image of the test element group may be obtained via SSRM (Scanning Spreading Resistance Microscopy) in S220 of FIG. 28. Referring to FIG. 30, the SSRM may be performed in a scan unit SU including the third reference well RPW.

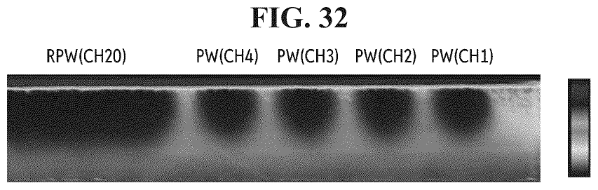

FIG. 32 is a resistance image of a scan unit SU including the third reference well RPW and the first wells PW adjacent to each other in the first direction DR1 and having first to fourth lengths CH1 to CH4 of FIG. 30 as obtained through SSRM. The resistance image of FIG. 32 represents a resistance value of a log scale. The red color represents a smaller value, and a blue color represents a larger value.

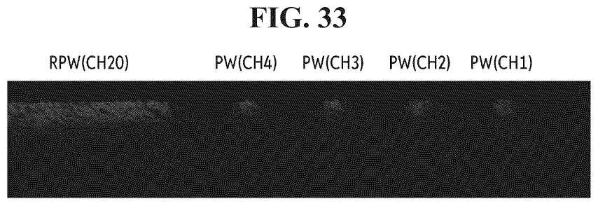

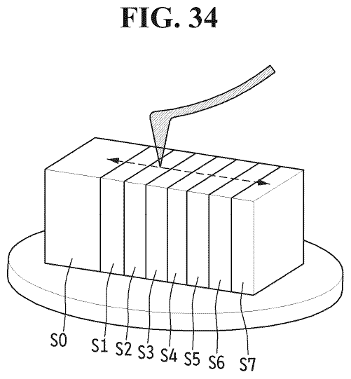

A carrier concentration image of the test element group may be generated from the resistance image of the test element group in S230 of FIG. 28. FIG. 33 is a carrier concentration image generated from the resistance image obtained through SSRM of FIG. 32. The carrier concentration image of FIG. 33 represents a carrier concentration value of a log scale, and the red color represents a smaller value, and the blue color represents a larger value. For example, referring to FIG. 34, in order to obtain the carrier concentration, SSRM may be performed on each of different samples S0 to S7 to obtain the resistance of each of the samples S0 to S7. Based on the resistance of each of the samples S0 to S7 and the concentration of carriers of each of the samples S0 to S7, the relationship between the concentration of carriers and the resistance may be calculated. The resistance image of FIG. 32 may be converted into the carrier concentration image of FIG. 33 using the relationship between the carrier concentration and the resistance.

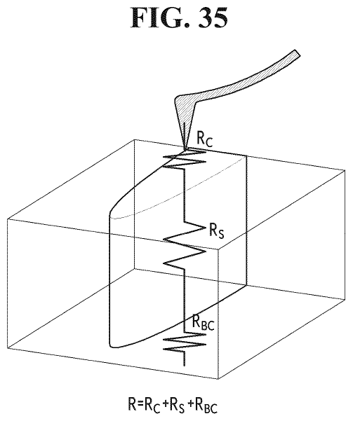

Referring to FIG. 35, a resistance R measured via the SSRM may be a sum of a contact resistance R_{C} due to the contact between the tip and the substrate 100, a resistance R_{S} of the first well PW, and a resistance R_{BC} of the substrate 100. Since the contact resistance R_{C} is relatively larger than each of the resistance R_{S} of the first well PW and the resistance R_{BC} of the substrate 100, the accuracy of the resistance image of FIG. 33 may be degraded. Therefore, the contact resistance R_{C} needs to be corrected.

An offset for correcting the contact resistance R_{C} may be determined using MSIMS and differential Hall effect metrology in S240 of FIG. 28.

Since the third reference well RPW of FIG. 30 has a relatively larger length CH20 in the first direction DR1, the third reference well RPW of FIG. 30 may be substantially the same as the first reference well RPW of FIG. 7. Therefore, the carrier concentration image of the third reference well RPW of FIG. 30 may be corrected under assuming that the concentration of carriers in the first reference well RPW of FIG. 7 is equal to the concentration of carriers in the third reference well RPW of FIG. 30.

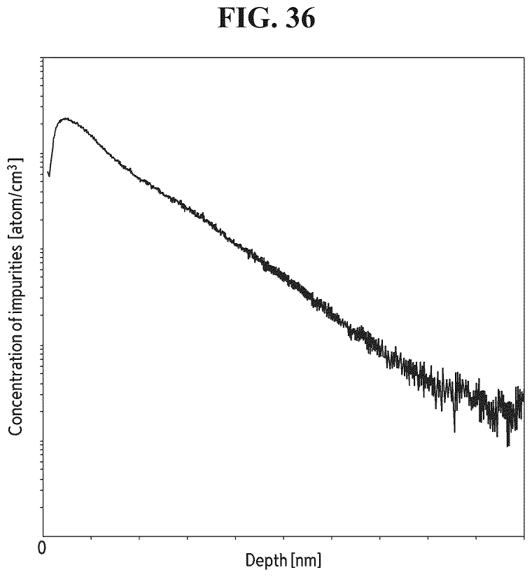

Specifically, referring to FIG. 36, the concentration of impurities per unit volume based on the depth of the first reference well RPW of FIG. 7 may be obtained via the MSIMS. The concentration of impurities per unit volume based on the depth of the first reference well RPW of FIG. 7 may be integrated with respect to the depth to calculate the concentration of impurities per unit area of the first reference well RPW of FIG. 7. The activity of the carrier may be calculated using a differential Hall effect metrology. Using the differential Hall effect metrology, the concentration of impurities per unit area of the first reference well RPW of FIG. 7 may be converted into the concentration of carriers of the first reference well RPW of FIG. 7.

An offset for correcting the contact resistance R_{C} may be determined using the carrier concentration image of the first reference well RPW of FIG. 7 and the carrier concentration image of the third reference well RPW of FIG. 33.

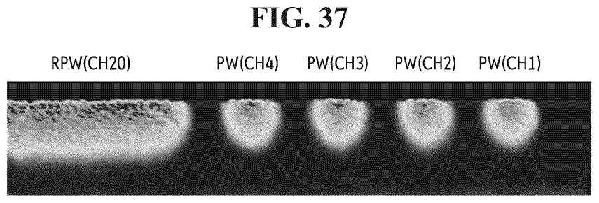

A final carrier concentration image of the test element group may be generated by applying the determined offset to the carrier concentration image of the test element group in S250 of FIG. 28. FIG. 37 is a final carrier concentration image generated by applying an offset to the carrier concentration image of FIG. 33. The final carrier concentration image of FIG. 37 represents a carrier concentration value of a log scale, and the red color represents a smaller value, and the blue color represents a larger value.

The concentration of carriers of the test element group may be calculated using the final carrier concentration image of the test element group in S260 of FIG. 28.

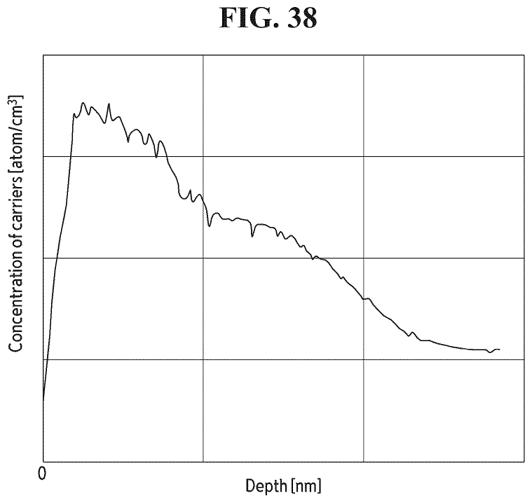

FIG. 38 is a graph of a carrier concentration based on a depth into which the final carrier concentration image of the third reference well RPW in FIG. 37 has been converted. The concentration of carriers based on the depth of FIG. 38 is integrated with respect to the depth to calculate the concentration of carriers per unit area.

Similarly, the method for analyzing a concentration of carriers of FIG. 28 may be performed using the second well NW of FIG. 31. Referring to FIG. 31, the SSRM may be performed in a scan unit SU including the fourth reference well RNW. For example, the resistance image may be obtained by performing SSRM with the scan unit SU including the fourth reference well RNW and the second wells NW adjacent to each other and having the first to fourth lengths CH1 to CH4 in the first direction DR1. The carrier concentration image may be generated from the resistance image using the sample as shown in FIG. 34. The concentration of impurities per unit volume based on the depth of the second reference well RNW of FIG. 8 may be obtained via the MSIMS as shown in FIG. 36. The concentration of impurities per unit volume based on the depth of the second reference well RNW of FIG. 8 may be integrated with respect to the depth to calculate the concentration of impurities per unit area of the second reference well RNW of FIG. 8. The concentration of impurities per unit area of the second reference well RNW of FIG. 8 may be converted into the concentration of carriers of the second reference well RNW of FIG. 8 using a differential Hall effect metrology. An offset for correcting the contact resistance R_{C} may be determined using the carrier concentration image of the second reference well RNW of FIG. 8 and the carrier concentration image of the fourth reference well RNW of FIG. 33. A final carrier concentration image may be generated by applying the determined offset to the carrier concentration image, and the carrier concentration may be calculated using the final carrier concentration image.

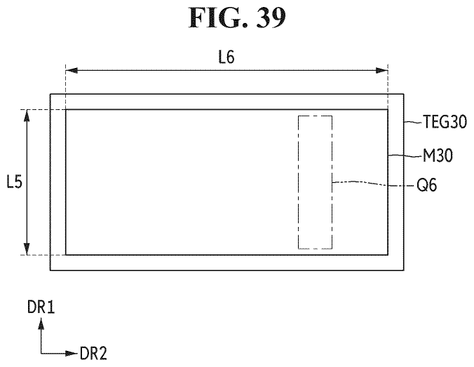

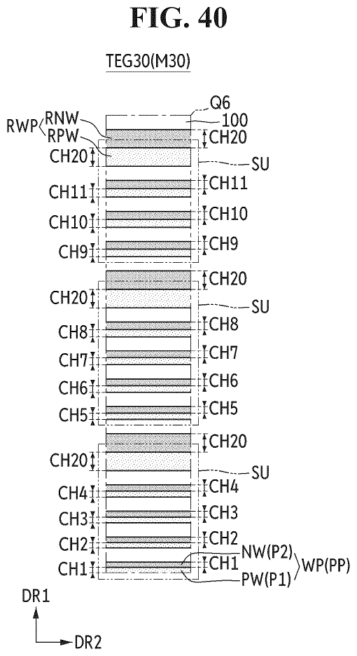

FIGS. 39 to 41 are diagrams for illustrating a method for analyzing a concentration of carriers in the semiconductor device of FIG. 28. FIG. 39 is a diagram illustrating a 30th test element group TEG30 and a 30th mask layout M30. FIG. 40 is an enlarged view of an area Q6 of FIG. 39.

Referring to FIGS. 39 and 40, the 30th test element group TEG30 may be formed on the scribe lane area SL of FIG. 1 in S210 of FIG. 28.

The 30th test element group TEG30 may include a first well PW and a second well NW formed using the 30th mask layout M30. The 30th mask layout M30 may include a first pattern P1 and a second pattern P2. The 30th mask layout M30 may include a pair of patterns or a pattern pair PP spaced apart from each other in the first direction DR1.

The pattern pair PP may include the first pattern P1 and the second pattern P2 that are adjacent to each other and have the same length in the first direction DR1. The pattern pairs PP having different lengths in the first direction DR1 may be respectively formed in areas of the 30th mask layout M30 isolated from each other via the pattern pair PP including the first pattern P1 and the second pattern P2 having the 20th length CH20 in the first direction DR1. Accordingly, the 30th test element group TEG30 may include a pair of wells or a well pair WP composed of the first well PW and the second well NW that are spaced apart from each other in the first direction DR1, and have a 20th length CH20 in the first direction DR1 and are adjacent to each other. Well pairs WP having different lengths in the first direction DR1 may be respectively formed in areas of the 30th test element group TEG30 isolated from each other via the well pair WP including the first well PW and the second well NW having the 20th length CH20 in the first direction DR1. The first well PW having a 20th length CH20 in the first direction DR1 may be referred to as a third reference well RPW, and the second well NW having a 20th length CH20 in the first direction DR1 may be referred to as a fourth reference well RNW. The third reference well RPW and the fourth reference well RNW neighboring each other may be referred to as a reference well pair RWP.

A final carrier concentration image corresponding to the scan unit SU may be generated by performing operations S220 to S250 of FIG. 28 on the scan units SU of the 29th test element group TEG29 of FIGS. 30 and 31 and the 30th test element group TEG30 of FIG. 40. A carrier concentration may be calculated by performing operation S260 of FIG. 28 on the final carrier concentration image.

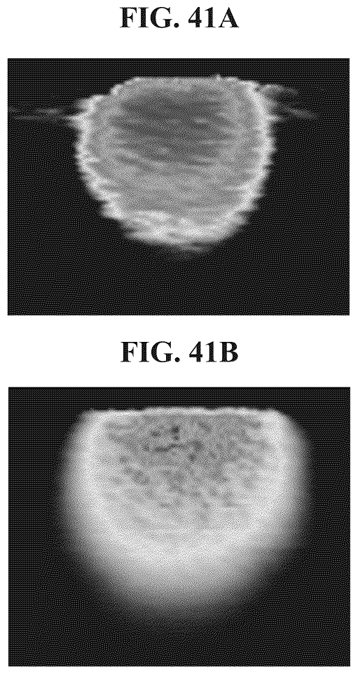

FIG. 41A is a final carrier concentration image of a second well NW having an i-th length CHi in the first direction DR1 and not in contact with another well of FIG. 31. FIG. 41B is a final carrier concentration image of the first well PW having an i-th length CHi in the first direction DR1 and not in contact with another well of FIG. 30. FIG. 41C is a final carrier concentration image of the first well PW having an i-th length CHi in the first direction DR1 and adjacent to the second well NW of FIG. 40.

Referring to FIGS. 41A, 41B and 41C, the concentration of carriers in the first well PW adjacent to the second well NW may be different from the concentration of carriers in the first well PW not adjacent to the second well NW. This may be due to a combination of a hole which is a carrier of the first well PW, and an electron which is a carrier of the second well NW, or a migration of an impurity of the first well PW to the second well NW.

A loss ratio of carriers in the first well PW when the first well PW is formed adjacent to the second well NW may be calculated using the concentration of carriers per unit area calculated from the final carrier concentration image of FIG. 41B and the concentration of carriers per unit area calculated from the final carrier concentration image of FIG. 41C. Alternatively, the carrier concentration per unit area calculated from the final carrier concentration image of FIG. 41B may be integrated with respect to the i-th length CHi of the first well PW of FIG. 30 to calculate the carrier concentration per unit length. The concentration of carriers per unit area calculated from the final carrier concentration image of FIG. 41C may be integrated with respect to the i-th length CHi of the first well PW of FIG. 40 to calculate the concentration of carriers per unit length. A loss ratio of carriers in the first well PW when the second well NW is formed adjacent to the first well PW may be calculated using the concentration of carriers per unit length of the first well PW of FIG. 30 and the concentration of carriers per unit length of FIG. 40. That is, in the method for analyzing a concentration of carriers of the semiconductor device according to some implementations, when two wells of different conductivity types are adjacent to each other, the loss ratio of carriers of each of the two wells may be directly calculated.

In addition, the reference concentration of impurities per unit area calculated through the Equation 1 may be integrated with respect to the i-th length CHi of the first well PW to calculate the concentration of impurities per unit length. Based on the concentration of impurities per unit length and the concentration of carriers per unit length, the activity of the carriers relative to the concentration of injected impurities may be calculated.

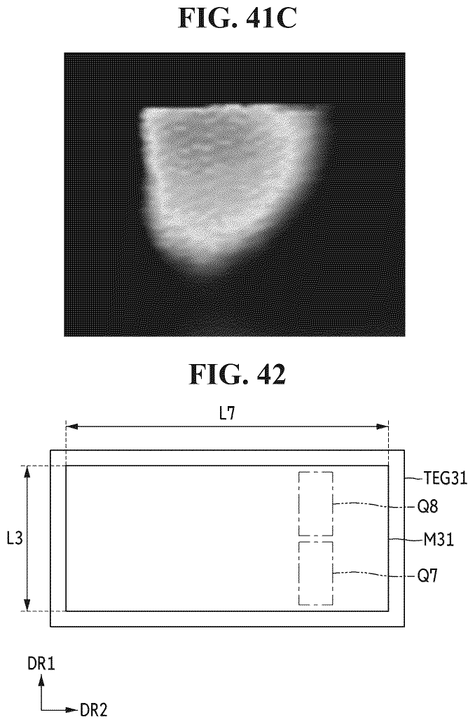

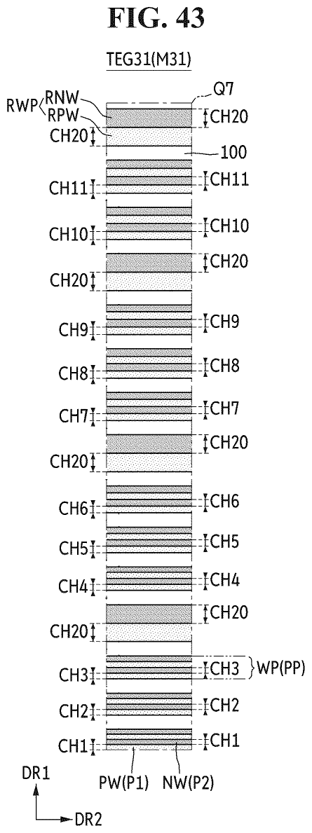

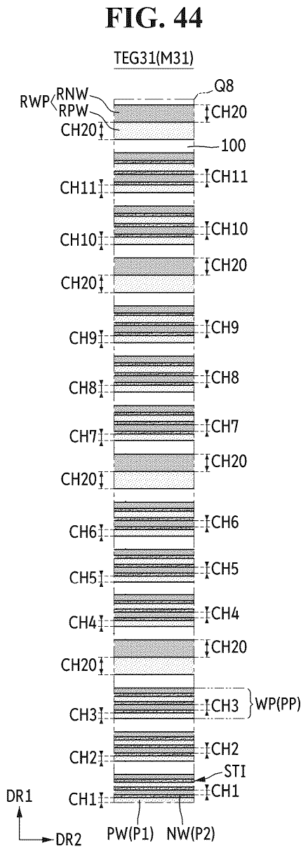

FIGS. 42 to 44 are diagrams for illustrating a method for analyzing a concentration of carriers in the semiconductor device of FIG. 28. For convenience of description, differences from those described with reference to FIGS. 1 to 41 will be mainly described. FIG. 42 is a diagram illustrating a 31st test element group TEG31 and a 31st mask layout M31. FIG. 43 is an enlarged view of an area Q7 of FIG. 42. FIG. 44 is an enlarged view of an area Q8 of FIG. 42.

Referring to FIGS. 42 to 44, a 31st test element group TEG31 may be formed on the scribe lane area SL of FIG. 1 in S210 of FIG. 28.

The 31st test element group TEG31 may include a first well PW and a second well NW formed using the 31st mask layout M31. The 31st mask layout M31 may include a first pattern P1 and a second pattern P2. The 31st mask layout M31 may include a pattern pair or a pair of patterns PP spaced apart from each other in the first direction DR1.

The pattern pairs PP including the first pattern P1 and the second pattern P2 having a 20th length CH20 in the first direction DR1 may be spaced apart from each other in the first direction DR1. Pattern pairs PP including two first patterns P1 and two second patterns P2 having the same length and alternately arranged with each other along the first direction DR1 may be respectively disposed in areas of the 31st mask layout M31 isolated from each other via the pattern pair PP including a first pattern P1 and a second pattern P2 having a 20th length CH20 in the first direction DR1.

Accordingly, the 31st test element group TEG31 may include the reference well pair RWP, and the well pairs WP having different lengths in the first direction DR1 respectively formed in the areas of the 31st test element group TEG31 isolated from each other via the reference well pair RWP. The pair of wells WP may include two first wells PW and two second wells NW that have the same length in the first direction DR1 and are alternately arranged with each other in the first direction DR1.

In a first area of the 31st test element group TEG31, the well pair WP may include two first wells PW and two second wells NW.

In a second area of the 31st test element group TEG31, the well pair WP may further include an element isolation film STI. The element isolation film STI may be disposed between the first well PW and the second well NW adjacent to each other. In some implementations, the length of the element isolation films STI in the first direction DR1 may be in a range of 10% to 100% of the length of the corresponding wells in the first direction. For example, a length of the element isolation film STI (in the first direction) disposed between the first well PW and the second well NW having a first length CH1 in the first direction may be in a range of 10% to 100% of the first length CH1. A length of the element isolation film STI (in the first direction) disposed between the first well PW and the second well NW having a tenth length CH10 in the first direction may be in a range of 10% to 100% of the tenth length CH10. In some implementations, the element isolation film STI do not include any impurities of the first conductivity type and/or the second conductivity type. For example, any impurities of the first conductivity type and/or the second conductivity type present in the element isolation films STI may be negligible compared to the impurities of the first conductivity type and/or the second conductivity type of the first wells PW and/or the second wells NW. The first conductivity type impurity in the first well PW and/or the second conductivity type impurity in the second well NW may diffuse into the element isolation film STI.

Operations S220 to S260 of FIG. 28 may be performed on the scan unit SU of the 31st test element group TEG31 of FIG. 43 to calculate the concentration of carriers corresponding to the scan unit. Based on a comparing result of the concentration of carriers per unit length of the first well PW of FIG. 30 with the concentration of carriers per unit length of the first well PW of FIG. 43, the loss ratio of the carriers of the first well PW when the second well NW is formed adjacent to each of both opposing sides in the first direction DR1 of the first well PW may be calculated. That is, in the method for analyzing a concentration of carriers in the semiconductor device according to some implementations, when one first well PW is adjacent to each of both opposing sides in the first direction DR1 of the second well NW, the loss ratio of carriers in the first well PW may be directly calculated.

Operations S220 to S260 of FIG. 28 may be performed on the scan unit of the 31st test element group TEG31 of FIG. 44 to calculate the concentration of carriers corresponding to the scan unit. Based on a comparing result of the concentration of carriers per unit length of the first well PW of FIG. 30 with the concentration of carriers per unit length of the first well PW of FIG. 44, the loss ratio of the carriers of the first well PW when the element isolation film STI is formed between the first well PW and the second well NW may be calculated. That is, in the method for analyzing a concentration of carriers in the semiconductor device according to some implementations, when the element isolation film STI is formed between the first well PW and the second well NW, the loss ratio of carriers in the first well PW may be directly calculated.

Referring to FIGS. 1 to 44, the semiconductor device according to some implementations may include various test element groups. The semiconductor device may include at least one test element group of first to 13th test element groups TEG1 to TEG13 each including a first well PW, first to 13th test element groups TEG1 to TEG13 each including a second well NW, a 14th test element group TEG14 including a first reference well RPW, a 15th test element group TEG15 including a second reference well RNW, 16th to 28th test element groups TEG16 to TEG28 each including a first well PW, 16th to 28th test element groups TEG16 to TEG28 each including a second well NW, a 29th test element group TEG29 including a first well PW and a third reference well RPW, a 29th test element group TEG29 including a second well NW and a fourth reference well RNW, a 30th test element group TEG30 including a pair of wells WP including one first well PW and one second well NW, and a reference well pair RWP, a 31st test element group TEG31 including a well pair WP composed of a plurality of first wells PW and a plurality of second wells NW and a reference well pair RWP, and a 31st test element group TEG31 including a well pair WP including a plurality of first wells PW, a plurality of second wells NW, and a plurality of element isolation films STI, and a reference well pair RWP.

The first to 31st test element groups TEG1 to TEG31 may be disposed on the scribe lane area SL in various manners. One cell area CA may include a first side surface and a second side surface opposite to each other in the first direction DR1, and a third side surface and a fourth side surface opposite to each other in the second direction DR2. For example, the first to 31st test element groups TEG1 to TEG31 may be disposed adjacent to one of the first to fourth side surfaces of one cell area CA. For example, at least two test element groups of the first to 31st test element groups TEG1 to TEG31 may be disposed adjacent to different side surfaces of the first to fourth side surfaces of one cell area CA.

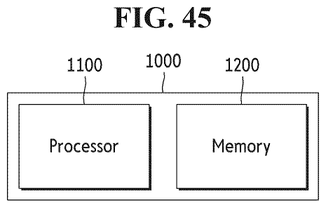

FIG. 45 is a diagram for illustrating a system for analyzing a concentration of impurities and a concentration of carriers according to some implementations.

An analysis device 1000 may be any electronic device including components for analyzing the concentration of impurities and the concentration of carriers. The analysis device 1000 may be a computer, a personal computer (PC), a laptop, or an experimental device. However, the present disclosure is not limited thereto.

The analysis device 1000 may include a processor 1100 that performs instructions for analyzing the concentration of impurities and the concentration of carriers, and a memory 1200 that stores therein the instructions. The processor 1100 may be a central processing unit (CPU), an application processor (AP), a digital signal processor (DSP), a graphics processing unit (GPU), a vision processing unit (VPU), or a neural processing unit (NPU), but is not limited thereto. The memory 1200 may be an on-chip memory, a cache memory, a random access memory (RAM), a read only memory (ROM), a solid state drive (SSD), a hard disk drive (HDD), or an optical disk drive (ODD), but is not limited thereto.

The method for analyzing the concentration of impurities described using FIGS. 1 to 44 may be performed by the analysis device 1000. For example, referring to FIG. 2, the analysis device 1000 may receive a concentration of impurities per unit area on a test element group basis, calculate a reference concentration of impurities per unit area on a test element group basis, and output a graph of the reference concentration of impurities per unit area and the concentration of impurities per unit area as shown in FIG. 15. In another example, referring to FIG. 28, the analysis device 1000 may receive a resistance image, generate a carrier concentration image as shown in FIG. 33, determine an offset to generate a final carrier concentration image as shown in FIG. 37, generate a graph of a carrier concentration based on a depth from the final carrier concentration image as shown in FIG. 38, and calculate the carrier concentration per unit area.

According to the aforementioned and other implementations of the present disclosure, there is provided a method for analyzing a concentration of impurities in a semiconductor device including forming a first test element group including a plurality of first wells spaced apart in a first direction and containing first impurities of a first conductivity type and a second test element group including a first reference well containing second impurities of the first conductivity type, each of the plurality of first wells having a first length in the first direction and the first reference well having a second length in the first direction greater than the first length, obtaining, via a MSIMS, a concentration of the first impurities per unit area of the first test element group and a concentration of the second impurities per unit area of the second test element group, calculating a concentration of reference impurities per unit area of the first test element group using the concentration of the second impurities per unit area of the second test element group and the first length, and comparing the concentration of reference impurities per unit area of the first test element group with the concentration of the first impurities per unit area of the first test element group.

While the present disclosure contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although implementations of the present disclosure have been described with reference to the accompanying drawings, the present disclosure is not limited to the above implementations, but may be realized in various different forms. A person skilled in the art may appreciate that the present disclosure may be practiced in other concrete forms without changing the technical spirit or essential characteristics of the present disclosure. Therefore, it should be appreciated that the implementations as described above is not restrictive but illustrative in all respects.

What is claimed is:

1. A semiconductor device comprising:
a substrate including a plurality of cell areas and a scribe lane area defining the plurality of cell areas;
a first test element group on the scribe lane area;
a second test element group on the scribe lane area; and
a third test element group on the scribe lane area,
wherein the first test element group includes a plurality of first wells spaced apart along a first direction and containing impurities of a first conductivity type,
wherein the second test element group includes a plurality of second wells spaced apart from each other along the first direction and containing impurities of the first conductivity type, and
wherein the third test element group includes a third well containing impurities of the first conductivity type.

2. The semiconductor device of claim 1, wherein each of the plurality of first wells has a first length in the first direction,
wherein each of the plurality of second wells has a second length different from the first length in the first direction, and
wherein a number of the plurality of first wells and a number of the plurality of second wells are equal to each other.

3. The semiconductor device of claim 1, wherein each of the plurality of first wells has a first length in the first direction,
wherein the plurality of first wells are spaced apart from each other by a first spacing along the first direction,
wherein each of the plurality of second wells has a second length different from the first length in the first direction,
wherein the plurality of second wells are spaced apart from each other by a second spacing along the first direction, wherein the first length and the first spacing are equal to each other, and
wherein the second length and the second spacing are equal to each other.

4. The semiconductor device of claim 1, comprising:
a fourth test element group on the scribe lane area;
a fifth test element group on the scribe lane area; and
a sixth test element group on the scribe lane area,
wherein the fourth test element group includes a plurality of fourth wells spaced apart from each other along the first direction and containing impurities of a second conductivity type different from the first conductivity type,
wherein the fifth test element group includes a plurality of fifth wells spaced apart from each other along the first direction and containing impurities of the second conductivity type, and
wherein the sixth test element group includes a sixth well containing impurities of the second conductivity type.

5. The semiconductor device of claim 4, wherein each of the plurality of fourth wells has a third length in the first direction,
wherein each of the plurality of fifth wells has a fourth length different from the third length in the first direction, and
wherein a number of the plurality of fourth wells is equal to a number of the plurality of fifth wells.

6. The semiconductor device of claim 4, wherein each of the plurality of fourth wells has a third length in the first direction,
wherein the plurality of fourth wells are spaced apart from each other by a third spacing along the first direction,
wherein each of the plurality of fifth wells has a fourth length different from the third length in the first direction,
wherein the plurality of fifth wells are spaced apart from each other by a fourth spacing along the first direction, wherein the third length and the third spacing are equal to each other, and
wherein the fourth length and the fourth spacing are equal to each other.

7. The semiconductor device of claim 4, comprising a seventh test element group on the scribe lane area,
wherein the seventh test element group includes a plurality of seventh wells spaced apart from each other in the first direction and containing impurities of the second conductivity type, and
wherein lengths in the first direction of the plurality of seventh wells are different from each other.

8. The semiconductor device of claim 1, comprising a fourth test element group on the scribe lane area,
wherein the fourth test element group includes a plurality of fourth wells spaced apart from each other in the first direction and containing impurities of the first conductivity type, and
wherein lengths in the first direction of the plurality of fourth wells are different from each other.

9. The semiconductor device of claim 1, comprising a fourth test element group on the scribe lane area,
wherein the fourth test element group includes a plurality of well pairs spaced apart from each other in the first direction, and
wherein each of the plurality of well pairs includes a fourth well containing impurities of the first conductivity type, and a fifth well containing impurities of a second conductivity type different from the first conductivity type, the fifth well being adjacent to the fourth well.

10. The semiconductor device of claim 9, wherein the plurality of well pairs include a first well pair and a second well pair spaced apart from each other in the first direction,
wherein the fourth well included in the first well pair has a first length in the first direction,
wherein the fifth well included in the first well pair has the first length in the first direction,
wherein the fourth well included in the second well pair has a second length different from the first length in the first direction, and
wherein the fifth well included in the second well pair has the second length in the first direction.

11. The semiconductor device of claim 1, comprising a fourth test element group on the scribe lane area,
wherein the fourth test element group includes a plurality of well pairs spaced apart from each other in the first direction,
wherein each of the plurality of well pairs includes a plurality of fourth wells containing impurities of the first conductivity type, and a plurality of fifth wells containing impurities of a second conductivity type different from the first conductivity type, and
wherein the plurality of fourth wells and the plurality of fifth wells are alternately arranged with each other in the first direction.

12. The semiconductor device of claim 11, wherein the plurality of well pairs include a first well pair and a second well pair spaced apart from each other in the first direction,
wherein each of the plurality of fourth wells included in the first well pair has a first length in the first direction,
wherein each of the plurality of fifth wells included in the first well pair has the first length in the first direction,
wherein each of the plurality of fourth wells included in the second well pair has a second length different from the first length in the first direction, and
wherein each of the plurality of fifth wells included in the second well pair has the second length in the first direction.

13. The semiconductor device of claim 11, wherein each of the plurality of well pairs includes an element isolation film disposed between each of the plurality of fourth wells and each of the plurality of fifth wells.

14. A semiconductor device comprising:
a substrate including a plurality of cell areas and a scribe lane area defining the plurality of cell areas;
a first test element group on the scribe lane area; and
a second test element group on the scribe lane area,
wherein the first test element group includes a first well and a first reference well spaced apart from each other in a first direction, wherein the first well and the first reference well contain impurities of a first conductivity type,
wherein the first well has a first length in the first direction,
wherein the first reference well has a second length greater than the first length in the first direction, and
wherein the second test element group includes a second well containing impurities of the first conductivity type.

15. The semiconductor device of claim 14, comprising a third test element group on the scribe lane area,
wherein the first test element group includes a third well and a third reference well, wherein the third well and the third reference well contain impurities of a second conductivity type different from the first conductivity type,
wherein the third well of the first test element group has a third length smaller than the second length in the first direction,
wherein the third reference well of the first test element group has the second length in the first direction, and
wherein the third test element group includes a fourth well containing impurities of the second conductivity type.

16. The semiconductor device of claim 14, wherein the first test element group includes a third well and a third reference well containing impurities of a second conductivity type different from the first conductivity type,
wherein the third well of the first test element group has the first length in the first direction and is adjacent to the first well in the first direction, and
wherein the third reference well of the first test element group has the second length in the first direction and is adjacent to the first reference well in the first direction.

17. The semiconductor device of claim 16, comprising an element isolation film disposed between the first well and the third well.

18. A semiconductor device comprising:
a substrate including a plurality of cell areas and a scribe lane area defining the plurality of cell areas;
a first test element group on the scribe lane area;
a second test element group on the scribe lane area; and
a third test element group on the scribe lane area,
wherein the first test element group includes a plurality of first wells spaced apart along a first direction and containing impurities of a first conductivity type,
wherein the second test element group includes a plurality of well pairs spaced apart from each other along the first direction,
wherein each of the plurality of well pairs includes a second well containing impurities of the first conductivity type and a third well containing impurities of a second conductivity type different from the first conductivity type, and
wherein the third test element group includes a fourth well containing impurities of the first conductivity type.

19. The semiconductor device of claim 18, wherein the plurality of cell areas include a first cell area,
wherein the first cell area includes a first side surface and a second side surface opposite to each other in the first direction, and a third side surface and a fourth side surface opposite to each other in a second direction intersecting the first direction, and
wherein the first test element group, the second test element group, and the third test element group are disposed adjacent to one of the first side surface, the second side surface, the third side surface, and the fourth side surface of the first cell area.

20. The semiconductor device of claim 18, wherein the plurality of cell areas include a first cell area,
wherein the first cell area includes a first side surface and a second side surface opposite to each other in the first direction, and a third side surface and a fourth side surface opposite to each other in a second direction intersecting the first direction, and
wherein at least two test element groups of the first test element group, the second test element group, and the third test element group are disposed adjacent to different side surfaces of the first cell area.
